(19) United States
(12) Patent Application Publication
(10) Pub. No.: US 2012/0199068 A1
(43) Pub. Date: Aug. 9, 2012

(54) MANUFACTURING APPARATUS FOR DEPOSITING A MATERIAL AND AN ELECTRODE FOR USE THEREIN

(76) Inventors: David Hillabrand, Midland, MI (US); Keith Mccoy, Midland, MI (US)

(21) Appl. No.: 13/500,410

(22) PCT Filed: Oct. 8, 2010
(86) PCT No.: PCT/US10/51970

§ 371 Date: Apr. 5, 2012

Related U.S. Application Data
(60) Provisional application No. 61/250,361, filed on Oct. 9, 2009.

(51) Int. Cl. C23C 16/50; H01B 5/00

(52) U.S. Cl. 118/723 E; 174/126.2; 118/723 R

(57) ABSTRACT

A manufacturing apparatus for deposition of a material on a carrier body and an electrode for use with the manufacturing apparatus are provided. The manufacturing apparatus includes a housing that defines a chamber. The housing also defines an inlet for introducing a gas into the chamber and an outlet for exhausting the gas from the chamber. At least one electrode is disposed through the housing with the electrode at least partially disposed within the chamber. The electrode has an exterior surface. The exterior surface has a contact region that is adapted to contact a socket. A contact region coating is disposed on the contact region of the electrode for maintaining electrical conductivity between the electrode and the socket. The contact region coating has an electrical conductivity of at least 7×10⁶ Siemens/meter at room temperature and a greater wear resistance than nickel as measured in mm³/N*m.

### RELATED APPLICATIONS

The subject patent application claims priority to, and all the benefits of, U.S. Provisional Patent Application Ser. No. 61/250,361 filed on Oct. 9, 2009. The entirety of this provisional patent application is expressly incorporated herein by reference.

### FIELD OF THE INVENTION

The present invention relates to a manufacturing apparatus. More specifically, the present invention relates to an electrode utilized within the manufacturing apparatus.

### BACKGROUND OF THE INVENTION

Manufacturing apparatuses for the deposition of a material on a carrier body are known in the art. Such manufacturing apparatuses comprise a housing that defines a chamber. Generally, the carrier body is substantially U-shaped, having a first end and a second end spaced from each other. Typically, a socket is disposed at each end of the carrier body. Generally, two or more electrodes are disposed within the chamber for receiving the respective socket disposed at the first end and the second end of the carrier body. The electrodes include an exterior surface having a contact region, which supports the socket and, ultimately, the carrier body to prevent the carrier body from moving relative to the housing. The contact region is the portion of the electrode adapted to be in direct contact with the socket and provides a primary current path from the electrode to the socket and into the carrier body.

A power supply device is coupled to the electrode for supplying an electrical current to the carrier body. The electrical current heats both the electrode and the carrier body to a deposition temperature. A processed carrier body is formed by depositing the material on the carrier body at the deposition temperature.

As known in the art, variations exist in the shape of the electrode and the socket to account for thermal expansion of the material deposited on the carrier body as the carrier body is heated to the deposition temperature. One such method utilizes a flat head electrode and a socket in the form of a graphite sliding block. The graphite sliding block acts as a bridge between the carrier body and the flat head electrode. The weight of the carrier body and the graphite sliding block acting on the contact region reduces the contact resistance between the graphite sliding block and the flat head electrode. Another such method involves the use of a two-part electrode. The two-part electrode includes a first half and a second half for compressing the socket. A spring element is coupled to the first half and the second half of the two-part electrode for providing a force to compress the socket. Another such method involves the use of an electrode defining a cup with the contact region located within the cup of the electrode. The socket is adapted to fit into the cup of the electrode and to contact the contact region located within the cup of the electrode. Alternatively, the socket may be structured as a cap that fits over the top of the electrode.

In some manufacturing apparatuses, a fouling of the electrode occurs on the contact region due to the buildup of deposits, especially when the material deposited on the carrier body is polycrystalline silicon that forms as a result of decomposition of chlorosilanes. The deposits result in an improper fit between the socket and the electrode over time. The improper fit causes small electrical arcs between the contact region and the socket that result in metal contamination of the material deposited on the carrier body. The metal contamination reduces the value of the carrier body, as the material deposited is less pure. Additionally, the fouling reduces the heat transfer between the electrode and the socket, resulting in the electrode reaching higher temperatures to effectively heat the socket and ultimately the carrier body. The higher temperatures of the electrode result in accelerated deposition of the material on the electrode. This is especially the case for electrodes that comprise silver or copper as the sole or main metal present therein.

The electrodes are typically continually subject to a mechanical cleaning operation to remove at least some of the deposits that form thereon during deposition of the material on the carrier body. The mechanical cleaning operation is typically performed on all portions of the electrode that are disposed in the chamber, including the contact region and the exterior surface of the electrode that is outside of the contact region.

The electrode must be replaced when one or more of the following conditions occur: first, when the metal contamination of the material being deposited upon the carrier body exceeds a threshold level; second, when fouling of the contact region of the electrode causes the connection between the electrode and the socket to become poor; third, when excessive operating temperatures for the electrode are required due to fouling of the contact region of the electrode. The electrode has a life determined by the number of carrier bodies the electrode can process before one of the above occurs. Whereas corrosion and deposit formation shorten the life of the electrode, wear attributable to the mechanical cleaning operation may also shorten the life of the electrode.

It is known in the art to provide silver plating over a stainless steel electrode. As known in the art, silver has higher thermal conductivity and lower electrical resistivity as compared to stainless steel and will provide immediate benefits relative to enhancing heat transfer and electrical conductivity properties of the electrode. Based upon the teachings of the prior art, providing silver plating over the stainless steel electrode is sufficient to satisfy the goals of enhancing heat transfer and electrical conductivity properties of the electrode. However, the prior art fails to address considerations relative to extending the useful life of electrodes.

It is also known in the art to form wear-resistance coatings on objects that are prone to wear, such as drill bits and cutting tools. However, electrodes are subject to numerous considerations that are immaterial to articles such as drill bits and cutting tools.

In view of the foregoing problems related to fouling and wear of the electrodes, there remains a need to further develop the structure of the electrodes to improve the productivity and increase the life of the electrodes.

### SUMMARY OF THE INVENTION AND ADVANTAGES

The present invention relates to a manufacturing apparatus for deposition of a material on a carrier body and an electrode for use with the manufacturing apparatus. The carrier body has a first end and a second end spaced from each other. A socket is disposed at each of the ends of the carrier body.

The manufacturing apparatus includes a housing that defines a chamber. The housing also defines an inlet for introducing a gas into the chamber and an outlet for exhausting the gas from the chamber. At least one electrode is disposed through the housing with the electrode at least partially disposed within the chamber for coupling to the socket. The electrode has an exterior surface. The exterior surface has a contact region that is adapted to contact the socket. A contact region coating is disposed on the contact region of the electrode for maintaining electrical conductivity between the electrode and the socket. The contact region coating has an electrical conductivity of at least 7×10⁶ Siemens/meter at room temperature and a greater wear resistance than nickel as measured in mm³/N*m. A power supply device is coupled to the electrode for providing an electrical current to the electrode.

There are many advantages to providing the contact region coating on the contact region of the electrode. One advantage is that it is possible to delay fouling of the electrode by selecting materials for the contact region coating based on the source of fouling. By delaying fouling, the life of the electrode is extended, resulting in a lower production cost and reducing the production time of the processed carrier bodies. Further, wear attributable to mechanical cleaning operations to which the electrode may be subject is minimized as compared to wear experienced when nickel or other metals having lesser wear resistance than nickel are used in the electrode or in coatings disposed on the exterior surface of the electrode. Such minimization of wear attributable to the mechanical cleaning operations is effective to further maximize life of the electrode.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1 is a cross-sectional view of a manufacturing apparatus for depositing a material on a carrier body including an electrode;

FIG. 2A is a first perspective view of an electrode utilized with the manufacturing apparatus of FIG. 1 showing an interior surface;

FIG. 2B is a second perspective view of the electrode of FIG. 2A defining a cup with a contact region located within a portion of the cup;

FIG. 3 is a cross-sectional view of the electrode of FIG. 2 taken along line 3-3 showing a contact region coating the contact region thereof;

FIG. 4 is an enlarged cross-sectional view of a portion of the electrode of FIG. 3 showing a socket disposed within the cup;

FIG. 5 is a cross-sectional view of the electrode of FIG. 3 with a portion of a circulating system connected thereto;

FIG. 6 is a cross-sectional view of another embodiment of the electrode of FIGS. 2 through 5 with a contact region coating, an exterior coating and a channel coating disposed on the electrode; and

FIG. 7 is a cross-sectional view of the manufacturing apparatus of FIG. 1 during the deposition of the material on the carrier body.

### DETAILED DESCRIPTION OF THE INVENTION

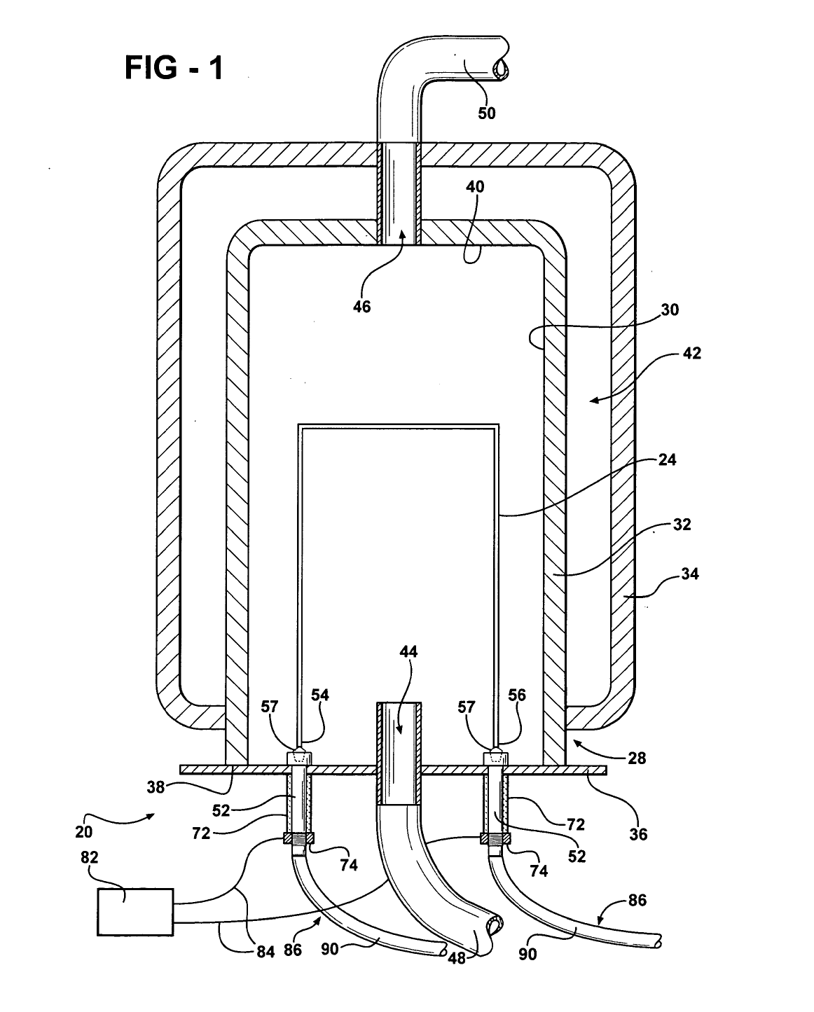

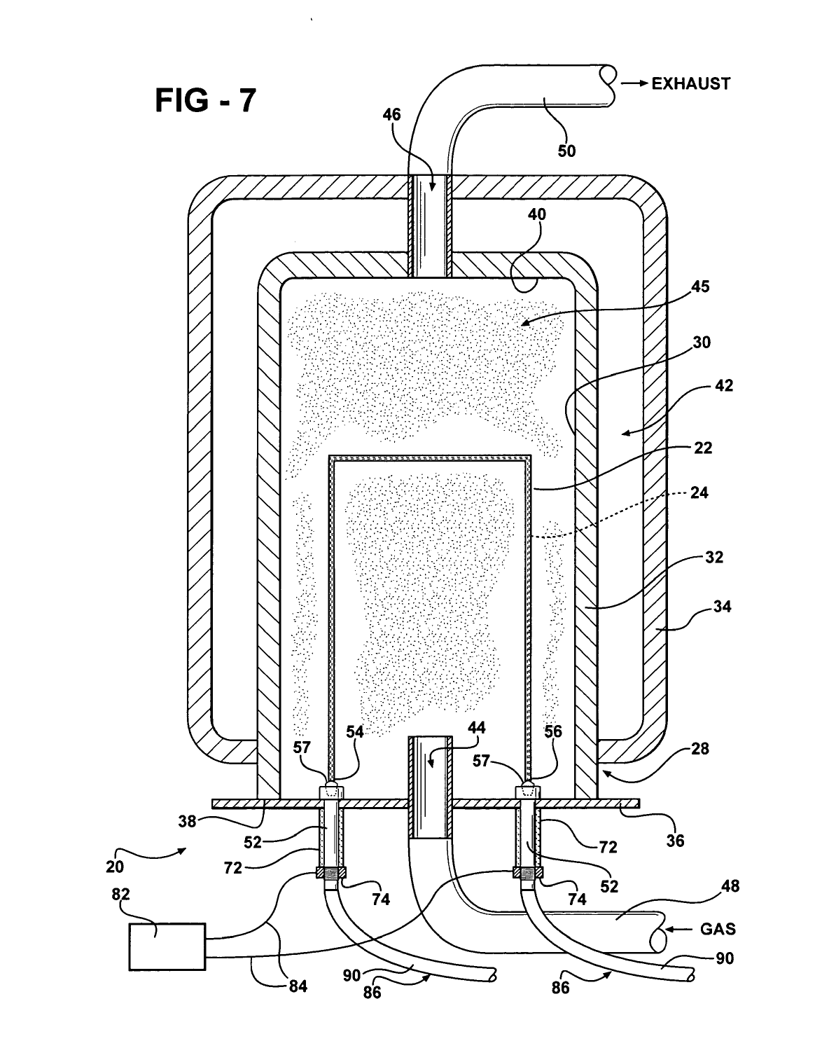

Referring to the Figures, wherein like numerals indicate like or corresponding parts throughout the several views, a manufacturing apparatus 20 for deposition of a material 22 on a carrier body 24 is shown in FIGS. 1 and 7. In one embodiment, the material 22 to be deposited is silicon; however, it is to be appreciated that the manufacturing apparatus 20 can be used to deposit other materials on the carrier body 24 without deviating from the scope of the subject invention.

Typically, with methods of chemical vapor deposition known in the art such as the Siemens method, the carrier body 24 is substantially U-shaped and has a first end 54 and a second end 56 spaced and parallel to each other. A socket 57 is disposed at each of the first end 54 and the second end 56 of the carrier body 24.

The manufacturing apparatus 20 includes a housing 28 that defines a chamber 30. Typically, the housing 28 comprises an interior cylinder 32, an outer cylinder 34 and a base plate 36. The interior cylinder 32 includes an open end 38 and a closed end 40 spaced from each other. The outer cylinder 34 is disposed about the interior cylinder 32 to define a void 42 between the interior cylinder 32 and the outer cylinder 34, typically serving as a jacket to house a circulated cooling fluid (not shown). It is to be appreciated by those skilled in the art that the void 42 can be, but is not limited to, a conventional vessel jacket, a baffled jacket, or a half-pipe jacket.

The base plate 36 is disposed on the open end 38 of the interior cylinder 32 to define the chamber 30. The base plate 36 includes a seal (not shown) disposed in alignment with the interior cylinder 32 for sealing the chamber 30 once the interior cylinder 32 is disposed on the base plate 36. In one embodiment, the manufacturing apparatus 20 is a Siemens type chemical vapor deposition reactor.

The housing 28 defines an inlet 44 for introducing a gas 45 into the chamber 30 and an outlet 46 for exhausting the gas 45 from the chamber 30. Typically, an inlet pipe 48 is connected to the inlet 44 for delivering the gas 45 to the housing 28 and an exhaust pipe 50 is connected to the outlet 46 for removing the gas 45 from the housing 28. The exhaust pipe 50 can be jacketed with a cooling fluid such as water or a commercial heat transfer fluid.

At least one electrode 52 is disposed through the housing 28 for coupling with the socket 57. In one embodiment, as shown in FIGS. 1 and 7, the at least one electrode 52 includes a first electrode 52 disposed through the housing 28 for receiving the socket 57 of the first end 54 of the carrier body 24 and a second electrode 52 disposed through the housing 28 for receiving the socket 57 of the second end 56 of the carrier body 24. It is to be appreciated that the electrode 52 can be any type of electrode known in the art such as, for example, a flat head electrode, a two-part electrode or a cup electrode. Further, the at least one electrode 52 is at least partially disposed within the chamber 30. In one embodiment, the electrode 52 is disposed through the base plate 36.

The electrode 52 is typically formed from a base metal having a minimum electrical conductivity at room temperature of from about 7×10⁶ to 42×10⁶ Siemens/meter or S/m. For example, the electrode 52 may be formed from a base metal selected from the group of copper, silver, nickel, Inconel®, gold, and combinations thereof, each of which meets the conductivity parameters set forth above. Additionally, the electrode 52 can comprise an alloy that meets the conductivity parameters set forth above. In one embodiment, the electrode 52 is formed from a base metal having a minimum electrical conductivity at room temperature of about 58×10⁶ S/m. Typically, the electrode 52 comprises copper, which has an electrical conductivity at room temperature of about 58×10⁶ S/m, and the copper is typically present in an amount of about 100% by weight based on the weight of the electrode 52. The copper can be oxygen-free electrolytic copper grade UNS 10100.

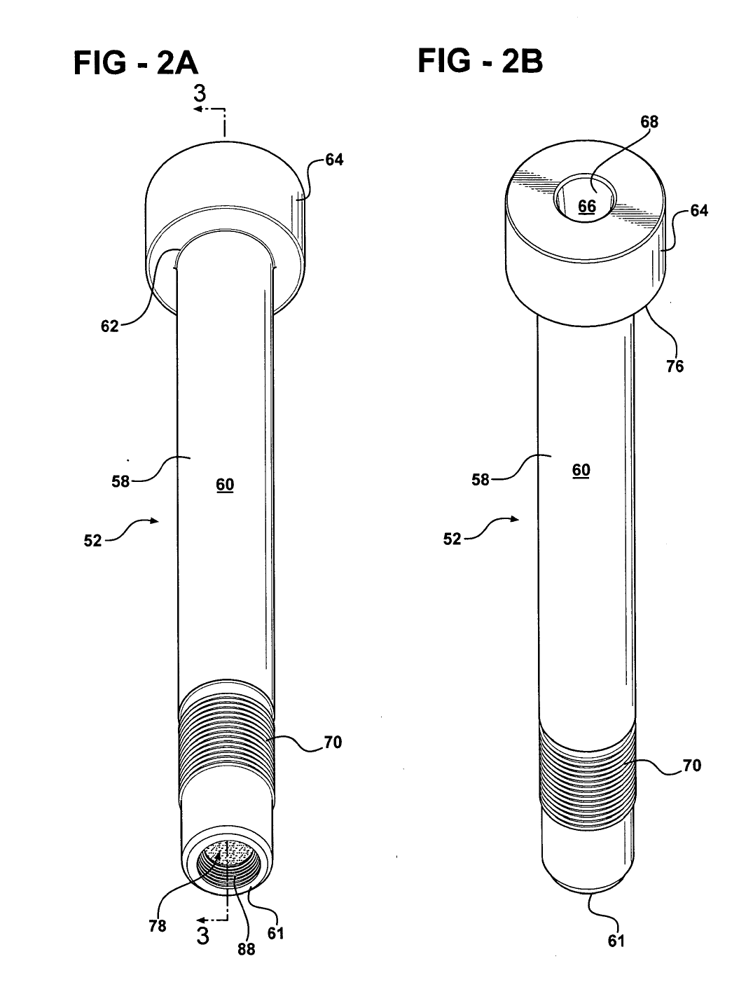

Referring also to FIGS. 2A-6, the electrode 52 has an exterior surface 60. The exterior surface 60 of the electrode 52 has a contact region 66. In particular, the contact region 66 as defined herein is the portion of the exterior surface 60 of the electrode 52 that is adapted to be in direct contact with the socket 57 and that provides a primary current path from the electrode 52 through the socket 57 and into the carrier body 24. As such, during normal operation of the manufacturing apparatus 20, the contact region 66 is shielded from exposure to the material 22 that is deposited on the carrier body 24. Because the contact region 66 is adapted to be in direct contact with the socket 57 and is generally not exposed to the material 22 during deposition on the carrier body 24, the contact region 66 is subject to different design considerations than other portions of the electrode 52, which considerations are described in further detail below.

In one embodiment, the electrode 52 includes a shaft 58 having a first end 61 and a second end 62. When present, the shaft 58 further defines the exterior surface 60 of the electrode 52. Generally, the first end 61 is an open end of the electrode 52. In one embodiment, the shaft 58 is generally cylindrically shaped and defines a diameter D₁ as shown in FIG. 4. However, it is to be appreciated that the shaft 58 can be a different shape such as a square, a circle, a rectangle, or a triangle without deviating from the subject invention.

The electrode 52 can also include a head 64 disposed on one of the ends 61, 62 of the shaft 58. It is to be appreciated that the head 64 can be integral to the shaft 58. Typically, when the head 64 is present, the contact region 66 is located on the head 64. It is to be appreciated by those skilled in the art that the method of connecting the socket 57 to the electrode 52 can vary between applications without deviating from the subject invention. For example, in one embodiment, such as for flat head electrodes (not shown), the contact region 66 can merely be a top, flat surface of the electrode 52 and the socket 57 can define a socket cup (not shown) that fits over the second end 62 of the electrode 52. In another embodiment, as shown in FIGS. 2A-6, the electrode 52 defines a cup 68 for receiving the socket 57. When the electrode 52 defines the cup 68, the contact region 66 is located within a portion of the cup 68. More specifically, the cup 68 has a bottom 102 and side walls 104, with the side walls 104 generally defining the cup 68 in a tapered form. For purposes of the instant application, the contact region 66 is only located on the side walls 104 of the cup 68. A bottom 102 of the cup 68 is not included in the designation of the contact region 66 because the socket 57 generally rests on the side walls 104 due to the tapered form of the cup 68. As such, electrical conductivity is generally not a consideration for the bottom 102 of the cup 68, whereas electrical conductivity is a consideration for the side walls 104 of the cup 68. In fact, under some circumstances, it may be desirable to minimize electrical conductivity of the bottom 102 of the cup 68, as described in further detail below. The socket 57 and the cup 68 can be designed such that the socket 57 can be removed from the electrode 52 when the carrier body 24 is harvested from the manufacturing apparatus 20. Typically, the head 64 defines a diameter D₂ that is greater than the diameter D₁ of the shaft 58. The base plate 36 defines a hole (not numbered) for receiving the shaft 58 of the electrode 52 such that the head 64 of the electrode 52 remains within the chamber 30 for sealing the chamber 30.

A first set of threads 70 can be disposed on the exterior surface 60 of the electrode 52. Referring back to FIG. 1, a dielectric sleeve 72 is typically disposed around the electrode 52 for insulating the electrode 52. The dielectric sleeve 72 can comprise a ceramic. A nut 74 is disposed on the first set of threads 70 for compressing the dielectric sleeve 72 between the base plate 36 and the nut 74 to secure the electrode 52 to the housing 28. It is to be appreciated that the electrode 52 can be secured to the housing 28 by other methods, such as by a flange, without deviating from the scope of the subject invention.

Typically, at least one of the shaft 58 and the head 64 include an interior surface 76 defining the channel 78. The interior surface 76 includes a terminal end 80 spaced from the first end 61 of the shaft 58. The terminal end 80 is generally flat and parallel to the first end 61 of the electrode 52. It is to be appreciated that other configurations of the terminal end 80 can be utilized such as a cone-shaped configuration, an ellipse-shaped configuration, or an inverted cone-shaped configuration (none of which are shown). The channel 78 has a length L that extends from the first end 61 of the electrode 52 to the terminal end 80. It is to be appreciated that the terminal end 80 can be disposed within the shaft 58 of the electrode 52 or the terminal end 80 can be disposed within the head 64 of the electrode 52, when present, without deviating from the subject invention.

The manufacturing apparatus 20 further includes a power supply device 82 coupled to the electrode 52 for providing an electrical current. Typically, an electric wire or cable 84 couples the power supply device 82 to the electrode 52. In one embodiment, the electric wire 84 is connected to the electrode 52 by disposing the electric wire 84 between the first set of threads 70 and the nut 74. It is to be appreciated that the connection of the electric wire 84 to the electrode 52 can be accomplished by different methods.

The electrode 52 has a temperature, which is modified by passage of the electrical current there through resulting in a heating of the electrode 52 and thereby establishing an operating temperature of the electrode 52. Such heating is known to those skilled in the art as Joule heating. In particular, the electrical current passes through the electrode 52, through the socket 57 at the contact region 66 of the electrode 52, and into the carrier body 24 resulting in the Joule heating of the carrier body 24. Additionally, the Joule heating of the carrier body 24 results in a radiant/convective heating of the chamber 30. The passage of electrical current through the carrier body 24 establishes an operating temperature of the carrier body 24.

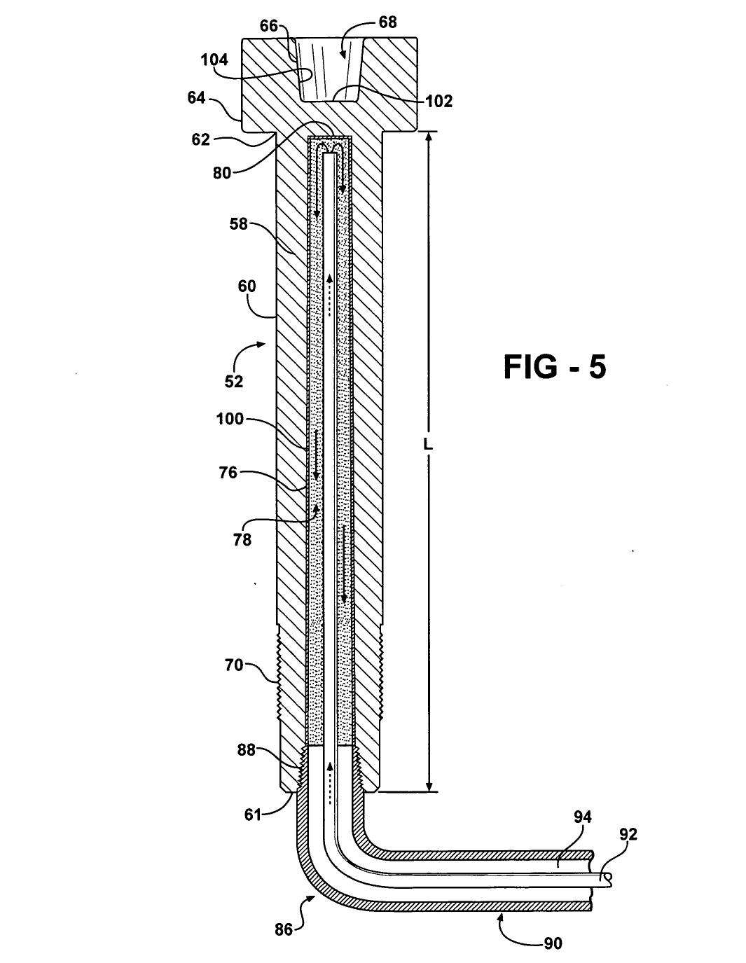

Referring to FIG. 5 and back to FIGS. 1 and 7, the manufacturing apparatus 20 can also include a circulating system 86 disposed within the channel 78 of the electrode 52. When present, the circulating system 86 is at least partially disposed within the channel 78. It is to be appreciated that a portion of the circulating system 86 can be disposed outside the channel 78. A second set of threads 88 can be disposed on the interior surface 76 of the electrode 52 for coupling the circulating system 86 to the electrode 52. However, it is to be appreciated by those skilled in the art that other fastening methods, such as the use of flanges or couplings, can be used to couple the circulating system 86 to the electrode 52.

The circulating system 86 includes a coolant in fluid communication with the channel 78 of the electrode 52 for reducing the temperature of the electrode 52. In one embodiment, the coolant is water; however, it is to be appreciated that the coolant can be any fluid designed to reduce heat through circulation without deviating from the subject invention. Moreover, the circulating system 86 also includes a hose 90 coupled between the electrode 52 and a reservoir (not shown). Referring only to FIG. 5, the hose 90 includes an inner tube 92 and an outer tube 94. It is to be appreciated that the inner tube 92 and the outer tube 94 can be integral to the hose 90 or, alternatively, the inner tube 92 and the outer tube 94 can be attached to the hose 90 by utilizing couplings (not shown). The inner tube 92 is disposed within the channel 78 and extends a majority of the length L of the channel 78 for circulating the coolant within the electrode 52.

The coolant within the circulating system 86 is under pressure to force the coolant through the inner tube 92 and the outer tubes 94. Typically, the coolant exits the inner tube 92 and is forced against the terminal end 80 of the interior surface 76 of the electrode 52 and subsequently exits the channel 78 via the outer tube 94 of the hose 90. It is to be appreciated that reversing the flow configuration such that the coolant enters the channel 78 via the outer tube 94 and exits the channel 78 via the inner tube 92 is also possible. It is also to be appreciated by those skilled in the art of heat transfer that the configuration of the terminal end 80 influences the rate of heat transfer due to the surface area and proximity to the head 64 of the electrode 52. As set forth above, the different geometric contours of the terminal end 80 result in different convective heat transfer coefficients for the same circulation flow rate.

In the embodiment of the electrode 52 shown in FIGS. 2A-6 that includes the cup 68, corrosion and deposit formation decreases the tolerance of the cup 68 and results in a poor fit between the socket 57 disposed on the carrier body 24 and the contact region 66 located within a portion of the cup 68 of the electrode 52. The poor fit results in small electrical arcs between the contact region 66 and the socket 57 as the electrical current is conducted from the electrode 52 to the carrier body 24. The small electrical arcs result in the metal of the electrode 52 being deposited on the carrier body 24, thereby resulting in a metal contamination of the material 22 deposited on the carrier body 24. As an example, in the manufacture of high purity silicon it is desirous to keep metallic contaminants at a minimum in the processed carrier body after deposition because the metallic contaminants contribute impurities to silicon ingots and wafers made from the processed carrier body. These metallic contaminants on the wafers can diffuse from the bulk wafer into active regions of micro-electronic devices made with the wafers during post processing of the micro-electronic devices. Copper, for example, is exceptionally prone to diffusion within the wafers if the concentration of copper in the processed carrier body is too high. Such problems with contamination are especially prevalent when the electrode 52 comprises exposed copper.

Generally, the electrode 52 must be replaced once the metal contamination exceeds the threshold level in polycrystalline silicon or once the material 22 is deposited on the electrode 52 and prevents the removal of the socket 57 from the cup 68 of the electrode 52 after processing. To illustrate this situation, copper contamination of polycrystalline silicon due to copper-based electrodes is typically below a threshold of 0.01 ppba. However, it is recognized to those skilled in the art of producing semiconductor materials of high purity that specifications for transition metal contamination differ based upon the particular application. For example, it is known that silicon used in the manufacture of ingots and wafers for photovoltaic cells can tolerate appreciably higher levels of copper contamination relative to semiconductor-grade silicon, e.g. 100-10,000 fold, without significant loss in lifetime and cell performance. As such, each purity specification for polycrystalline silicon may be evaluated individually when viewed against the electrode replacement need.

Nickel is a common material that may be included in the electrode 52, as indicated above. Nickel has also been included in exterior coatings on electrodes 52, especially on electrodes 52 used in manufacturing apparatuses in which polycrystalline silicon is formed, due to the fact that nickel is less contaminating to the polycrystalline silicon than copper (which is also commonly included in the electrodes). However, a nickel coating on a copper substrate has low wear resistance of about 1.5×10⁻⁵ mm³/N*m, and silver and gold have similarly low wear resistance, which can accelerate the demise of the electrode 52.

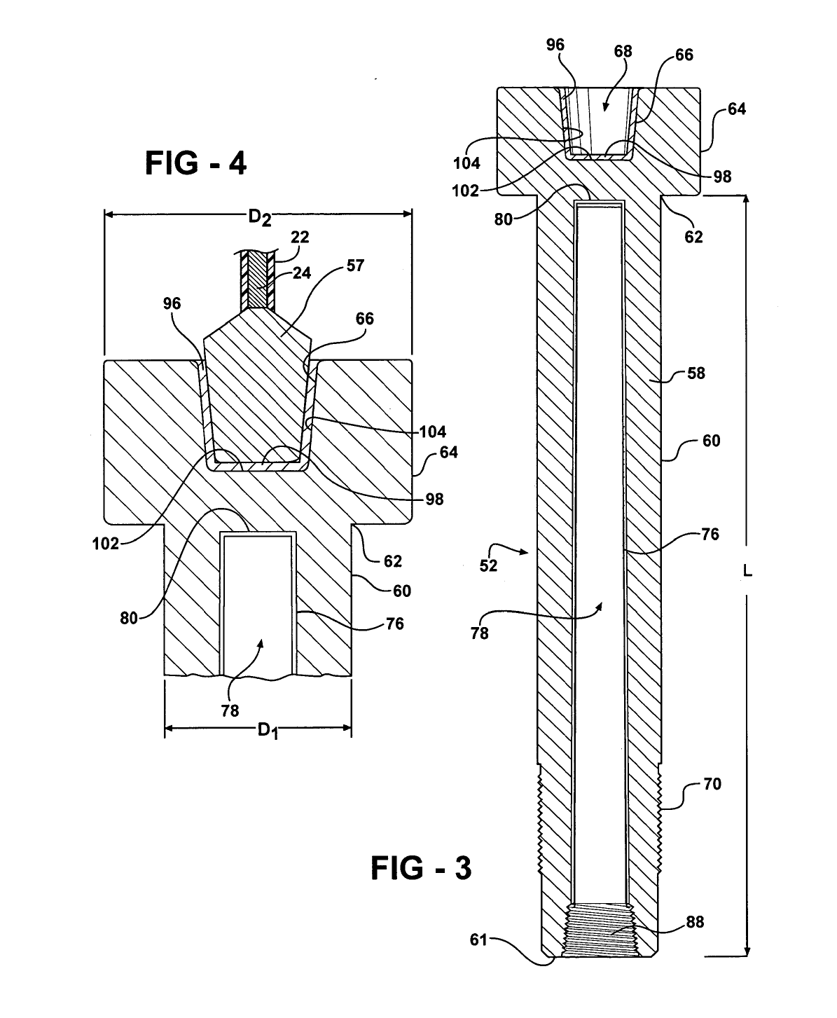

Referring to FIGS. 3, 4, and 6, the electrode 52 includes a contact region coating 96 disposed on the contact region 66 of the electrode 52. Typically, the contact region coating 96 is disposed directly on the base metal of the electrode 52, i.e., with no additional layers disposed between the contact region coating 96 and the base metal of the electrode 52. The contact region coating 96 has an electrical conductivity of at least 7×10⁶ Siemens/meter, more typically at least 20×10⁶ S/m, most typically at least 40×10⁶ S/m, each as measured at room temperature, with the upper limit of electrical conductivity not limited. Due to a greater importance of electrical conductivity for the contact region coating 96 than for other portions of the electrode 52 that are not in the primary current path between the electrode 52 and the carrier body 24, and because the contact region coating 96 is in contact with the socket 57 during deposition and is somewhat shielded from the material 22 deposited on the carrier body, specific materials are chosen for use in the contact region coating 96 that satisfy the electrical conductivity properties set forth above.

The electrode 52 is continually subject to a mechanical cleaning operation to remove deposits that may have formed thereon during deposition of the material 22 on the carrier body 24. The mechanical cleaning operation is typically performed on all portions of the electrode 52 that are disposed in the chamber 30, especially the contact region 66. When the electrode 52 defines the cup 68 with the contact region 66 located within a portion of the cup 68, the cup 68 is generally subject to elevated abrasive forces from the mechanical cleaning operation due to the shape of the cup 68. Due to the wear associated with the mechanical cleaning operation, the contact region coating 96 also has a greater wear resistance than nickel as measured in mm³/N*m, which enhances the overall wear resistance of the electrode 52. Wear resistance can be measured by ASTM G99-5 “Standard Test Method for Wear Testing with Pin-on-Disk Apparatus”. The contact region coating 96 typically has a wear resistance of at least 6×10⁶ mm³/N*m, alternatively at least 1×10⁸ mm³/N*m, which is many orders of magnitude higher than wear resistance of nickel.

In one embodiment, the contact region coating 96 may be further defined as one of a physical vapor deposition (PVD) coating or a plasma-assisted chemical vapor deposition (PCVD) coating. In another embodiment, the contact region coating 96 is further defined as a dynamic compound deposition coating. Dynamic Compound Deposition (DCD) is a proprietary low temperature coating process practiced by Richter Precision, Inc. of East Petersburg, Pa. The PVD, PCVD, and DCD coatings are typically formed from materials that are difficult to electroplate, but that provide enhanced properties to the electrode 52 as indicated above. The dynamic compound deposition coating 96 possesses a considerably decreased friction coefficient and increased durability as compared to coatings formed through other techniques.

The contact region coating 96 typically comprises a titanium-containing compound having electrical conductivity of at least 7×10⁶ Siemens/meter at room temperature. Suitable such titanium-containing compounds may be selected from the group of titanium nitride, titanium carbide, and combinations thereof. The contact region coating 96 may include other metals and/or compounds so long as sufficient electrical conductivity of the overall contact region coating 96 of at least 7×10⁶ Siemens/meter at room temperature is achieved for the contact region coating 96. For example, in one embodiment, the contact region coating 96 may further include at least one of silver, nickel, chromium, gold, platinum, palladium; and alloys thereof, such as a nickel/silver alloy; and titanium oxide, which does not possess sufficient electrical conductivity itself but which can be combined with electrically-conductive titanium-containing compounds (such as those set forth above) to result in the contact region coating 96 having sufficient electrical conductivity. Typically, the contact region coating 96 includes substantially only the titanium-containing compounds having the electrical conductivity of at least 7×10⁶ Siemens/meter at room temperature. However, when one or more of the other metals or compounds are present, the total amount of the titanium-containing compounds having the electrical conductivity of at least 7×10⁶ Siemens/meter at room temperature is typically at least 50% by weight based on the total weight of the contact region coating 96.

The titanium-containing compounds having electrical conductivity of at least 7×10⁶ Siemens/meter at room temperature have sufficient electrical conductivity and wear resistance such that the titanium-containing compounds are ideal for the contact region coating 96. The titanium-containing compounds are also difficult to electroplate. As such, the titanium-containing compounds are ideally included in PVD or PCVD coatings.

The contact region coating 96 extends the life of the electrode by providing a higher wear resistance than the materials that are generally used to form the electrode 52. Further, because wear resistance of the electrode 52 at the contact region 66 is one factor that controls whether or not the electrode 52 must be replaced, selection of materials for the contact region coating 96 based on wear resistance can be more effective in extending the life of the electrode 52 than selection of materials for other portions of the electrode 52 where wear resistance may be a lesser concern. Therefore, the specific type of material used for the contact surface coating 96 must resist wear while still possessing acceptable electrical conductivity as indicated above.

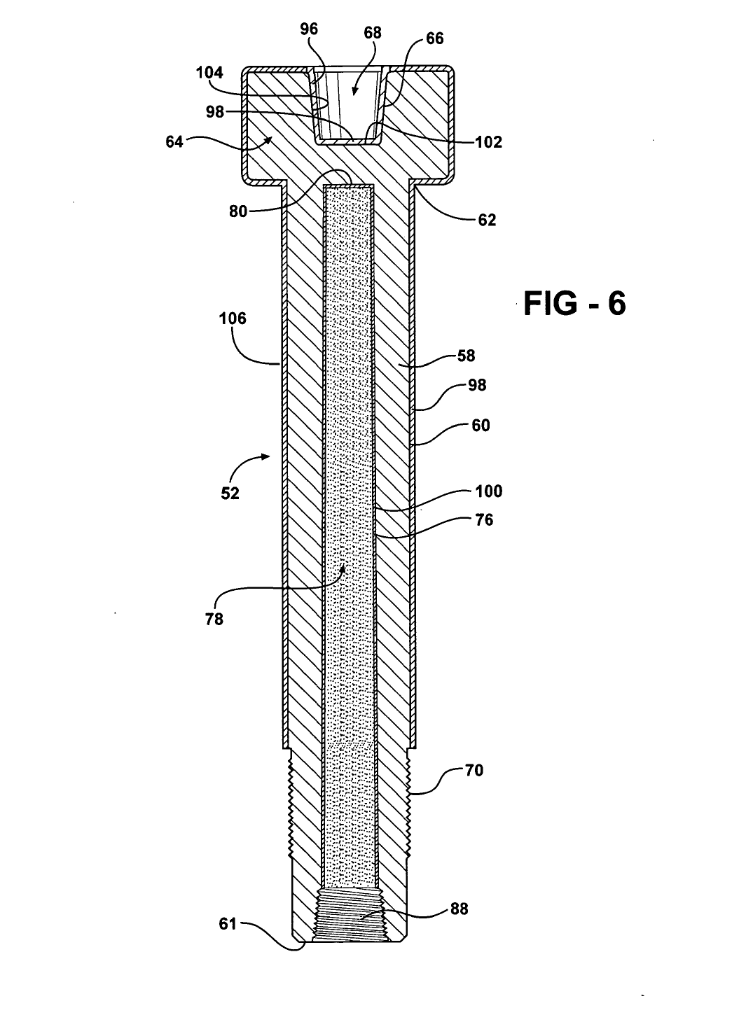

Wear resistance is also a desirable feature in other locations of the electrode 52 outside of the contact region 66 because the mechanical cleaning operation is typically performed on all portions of the electrode 52 that are disposed in the chamber 30, including the exterior surface 60 of the electrode outside of the contact region 66. As such, the electrode 52 can be coated in locations other than the contact region 66 for extending the life of the electrode 52. Referring to FIG. 6, in one embodiment the electrode 52 includes an exterior coating 98 disposed on the exterior surface 60 thereof outside of the contact region 66. In particular, the exterior coating 98 can be disposed on at least one of the head 64, outside of the contact region 66, and the shaft 58 of the electrode 52. Stated differently, the exterior coating 98 can be disposed on the head 64 outside of the contact region 66, on the shaft 58, or on both the head 64 outside of the contact region 66 and on the shaft 58.

The exterior coating 98 may be different than the contact region coating 96. In particular, the exterior coating 98 may comprise different material and/or may be formed through different techniques than the contact region coating 96. The type of material used for the contact region coating 96 or exterior coating 98 may differ due to consideration of physical properties such as electrical conductivity. For example, as indicated above, electrical conductivity of the contact region 66 is of greater concern than for other portions of the electrode 52 that are not in the primary current path between the electrode 52 and the carrier body 24. As such, the contact region coating 96 possesses electrical conductivity of at least 7×10⁶ Siemens/meter at room temperature whereas the exterior coating 98 is not required to possess electrical conductivity.

The titanium-containing compounds having the electrical conductivity of at least 7×10⁶ Siemens/meter at room temperature have excellent corrosion resistance, especially against chlorosilanes at high reactor temperatures, such that the titanium-containing compounds are also suitable for the exterior coating 98 outside of the contact region 66. More specifically, it is to be appreciated that the titanium-containing compounds are suitable for the exterior coating 98 that is disposed on the exterior surface 60 of the electrode 52 outside of the contact region 66 due to the excellent wear and corrosion resistance properties thereof, even though electrical conductivity is immaterial outside of the contact region 66 of the electrode 52. Platinum and rhodium are also suitable for the exterior coating 98 outside of the contact region 66 due to the fact that both platinum and rhodium exhibit silicide formation at a higher temperature than nickel (thereby providing benefits in terms of corrosion resistance).

Because electrical conductivity is immaterial outside of the contact region 66 of the electrode 52, materials other than the titanium-containing compounds having the electrical conductivity of at least 7×10⁶ Siemens/meter at room temperature, platinum, or rhodium can be used for the exterior coating 98 that is disposed on the exterior surface 60 of the electrode 52 outside of the contact region 66. As such, when the exterior coating 98 is disposed on the exterior surface 60 of the electrode 52 outside of the contact region 66, materials may be selected based upon their ability to enhance thermal reflectivity, thermal conductivity, purity, and deposit release properties with less focus on electrical conductivity. For example, when the exterior coating 98 is disposed on the exterior surface 60 of the electrode 52 outside of the contact region (as shown in FIG. 6), the exterior coating 98 may have any electrical conductivity, including an electrical conductivity of less than 7×10⁶ Siemens/meter at room temperature.

When the exterior coating 98 has an electrical conductivity of less than 7×10⁶ Siemens/meter at room temperature, the exterior coating 98 may comprise, but is not limited to, a diamond-like carbon compound. Diamond-like carbon compounds are known in the art and are identifiable by those of skill in the art. As known in the art, naturally occurring diamond has a purely cubic orientation of sp³ bonded carbon atoms. Diamond growth rates from molten material in both natural and bulk synthetic diamond production methods are slow enough that the lattice structure has time to grow in the cubic form that is possible for sp³ bonding of carbon atoms. In contrast, diamond-like carbon coatings can be produced by several methods which result in unique final desired coating properties to match the application requirements. As such, both cubic and hexagonal lattices can be randomly intermixed, layer by atomic layer, because there is no time available for one of the crystalline geometries to grow at the expense of the other before the atoms are “frozen” in place in the material. As a result, amorphous diamond-like carbon coatings can result that have no long range crystalline order. Such lack of long range crystalline order provides advantages in that there are no brittle fracture planes, so such coatings are flexible and conformal to the underlying shape being coated, while still being as hard as diamond.

Coatings comprising diamond-like carbon compounds are commercially available from Richter Precision, Inc. under the tradename Tribo-kote™. The exterior coating 98 comprising the diamond-like carbon compound, in particular, possesses excellent thermal reflectivity, thermal conductivity, purity, and deposit release properties, which are ideal for the exterior surface 60 of the electrode outside of the contact region 66 and in the chamber 30 because the exterior surface 60 of the electrode 52 outside of the contact region 66 is exposed to the chamber 30 and to the material 22 during deposition on the carrier body 24. In particular, the diamond-like carbon compound typically has a specular reflectance of from 10 to 20% in the far IR wavelengths of from 15 to 30 microns, 25 to 33% in the near IR wavelengths of from 1000 to 2500 nm, and from 10 to 26% in the UV-visible wavelengths of less than 500 nm, as measured with a Lambda 19 spectrophotometer from Perkin Elmer. When used, the diamond-like carbon compound is typically present in the exterior coating 98 in an amount of greater than 95% by weight based on the total weight of the exterior coating 98. More typically, the exterior coating 98 comprises only the diamond-like carbon compound when used. The diamond-like carbon compounds are typically deposited through dynamic coating deposition techniques (as described above), although it is to be appreciated that the instant invention is not limited to deposition of the diamond-like carbon coating through any particular technique.

As an alternative to the diamond-like carbon, titanium oxide is also suitable for the exterior coating 98 outside of the contact region 66. Titanium oxide, although possessing insufficient electrical conductivity to be used alone for the contact region coating 96, has excellent specular reflectivity such that the titanium oxide may be particularly suitable for the exterior coating 98 outside of the contact region 66. In particular, the titanium oxide typically has a specular reflectance of from 58 to 80% in the far IR wavelengths of from 1 to 30 microns, from 5 to 66% in the near IR wavelengths of from 1000 to 1500 nm, from 30 to 66% in the near IR wavelengths of from 1500 to 2500 nm, and from 40 to 65% in the UV-visible wavelengths of less than 500 nm. As such, titanium oxide can provide significant advantages relative to higher spectral reflectance.

The contact region coating 96, as well as the exterior coating 98 outside of the contact region 66, typically has a thickness of from about 0.1 μm to about 5 μm. While not shown in the Figures, it is to be appreciated that the contact region coating 96 and the exterior coating 98 may comprise multiple individual layers having a common compositional makeup, such as for purposes of achieving higher effective thicknesses of the contact region coating 96 and the exterior coating 98. Further, it is to be appreciated that additional coatings may be disposed over the contact region coating 96 and/or exterior coating 98 without deviating from the scope of the instant invention.

Based upon the above, it is clear that the content of the contact region coating 96 may be different from the exterior coating 98. When the electrode 52 defines the cup 68 with the contact region 66 located within a portion of the cup 68, the exterior coating 98 on a bottom 102 of the cup 68 may be different than the contact region coating 96 on the side walls 104 of the cup 68 due to the fact that electrical conductivity may not be a concern with the bottom 102 of the cup 68. As such, the exterior coating 98 that is disposed on the bottom 102 of the cup 68 may have an electrical conductivity of less than 7×10⁶ Siemens/meter at room temperature and may comprise the diamond-like carbon compound, which has excellent thermal reflectivity, thermal conductivity, purity, and deposit release properties as well as excellent wear resistance. Furthermore, the exterior coating 98 that is disposed on the bottom 102 of the cup 68 having an electrical conductivity of less than 7×10⁶ Siemens/meter at room temperature may effectively prevent arcing between the bottom 102 of the cup 68 and the socket 57 when the socket 57 is not in contact with the bottom 102 of the cup 68.

Selective coating of the electrode 52 may also be desirable under some circumstances, depending upon factors such as the particular base metal of the electrode 52, the material 22 that is deposited on the carrier body 56, and the conditions under which the manufacturing apparatus is intended to be used. In one embodiment, as shown in FIGS. 3-5, the exterior surface 60 of the electrode 52 is free from a coating, including the exterior coating 98, outside of the contact region 66 of the electrode 52. When the electrode 52 includes the head 64 and the shaft 58, at least one of the head, outside of the contact region 66, and the shaft 58 may be free from a coating disposed on the exterior surface 60 thereof.

As alluded to above, the electrode 52 having the contact region coating 96 and, optionally, the exterior coating 98 may exhibit corrosion resistance to gases present in the chamber 30 during operation of the manufacturing apparatus 20. In particular, the electrodes 52 may exhibit excellent resistance to hydrogen and trichlorosilane at elevated temperatures of up to 450° C. For example, the electrode 52 having the contact region coating 96 and, optionally, the exterior coating 98 may exhibit either no change or a positive change in weight after exposure to an atmosphere of hydrogen and trichlorosilane gas at a temperature of 450° C. for a period of 5 hours, along with low or no surface bubbling or degradation (as determined through visual observation), thereby indicating low or no corrosion of the electrode 52 or various coatings 96, 98 by the gases. Although some weight loss is acceptable (indicating surface degradation), such weight loss is typically less than or equal to 20% by weight, alternatively less than or equal to 15% by weight, alternatively less than or equal to 10% by weight of the total weight of the second exterior coating 106, with no weight loss preferred. However, it is to be appreciated that the electrodes 52 of the instant invention are not limited to any particular physical properties with regard to corrosion resistance.

In addition, a channel coating 100 can be disposed on the interior surface 76 of the electrode 52 for maintaining the thermal conductivity between the electrode 52 and the coolant. Generally, the channel coating 100 has a higher resistance to corrosion that is caused by the interaction of the coolant with the interior surface 76 as compared to the resistance to corrosion of the electrode 52. The channel coating 100 typically includes a metal that resists corrosion and that inhibits buildup of deposits. For example, the channel coating 100 can comprise at least one of silver, gold, nickel, chromium, and alloys thereof, such as a nickel/silver alloy. Typically, the channel coating 100 is nickel. The channel coating 100 has a thermal conductivity of from 70.3 to 427 W/m K, more typically from 70.3 to 405 W/m K and most typically from 70.3 to 90.5 W/m K. The channel coating 100 also has a thickness of from 0.0025 mm to 0.026 mm, more typically from 0.0025 mm to 0.0127 mm and most typically from 0.0051 mm to 0.0127 mm.

It is to be appreciated that the electrode 52 can include an anti-tarnishing layer (not shown) disposed on the channel coating 100. The anti-tarnishing layer is a protective thin film organic layer that is applied on top of the channel coating 100. Protective systems such as Technic Inc.'s Tarniban™ can be used following the formation of the channel coating 100 of the electrode 52 to reduce oxidation of the metal in the electrode 52 and in the channel coating 100 without inducing excessive thermal resistance. For example, in one embodiment, the electrode 52 can comprise silver and the channel coating 100 can comprise silver with the anti-tarnishing layer present for providing enhanced resistance to the formation of deposits compared to pure silver. Typically, the electrode 52 comprises copper and the channel coating 100 comprises nickel for maximizing thermal conductivity and resistance to the formation of deposits, with the anti-tarnishing layer disposed on the channel coating 100.

A typical method of deposition of the material 22 on the carrier body 24 is discussed below and refers to FIG. 7. The carrier body 24 is placed within the chamber 30, such that the sockets 57 disposed at the first end 54 and the second end 56 of the carrier body 24 are disposed within the cup 68 of the electrode 52 and the chamber 30 is sealed. The electrical current is transferred from the power supply device 82 to the electrode 52. A deposition temperature is calculated based on the material 22 to be deposited. The operating temperature of the carrier body 24 is increased by direct passage of the electrical current to the carrier body 24 so that the operating temperature of the carrier body 24 exceeds the deposition temperature. The gas 45 is introduced into the chamber 30 once the carrier body 24 reaches the deposition temperature. In one embodiment, the gas 45 introduced into the chamber 30 comprises a halosilane, such as a chlorosilane or a bromosilane. The gas can further comprise hydrogen. However, it is to be appreciated that the instant invention is not limited to the components present in the gas and that the gas can comprise other deposition precursors, especially silicon containing molecular such as silane, silicon tetrachloride, and tribromosilane. In one embodiment, the carrier body 24 is a silicon slim rod and the manufacturing apparatus 20 can be used to deposit silicon thereon. In particular, in this embodiment, the gas typically contains trichlorosilane and silicon is deposited onto the carrier body 24 as a result of the thermal decomposition of trichlorosilane. The coolant is utilized for preventing the operating temperature of the electrode 52 from reaching the deposition temperature to ensure that silicon is not deposited on the electrode 52. The material 22 is deposited evenly onto the carrier body 24 until a desired diameter of material 22 on the carrier body 24 is reached.

Once the carrier body 24 is processed, the electrical current is interrupted so that the electrode 52 and the carrier body 24 stop receiving the electrical current. The gas 45 is exhausted through the outlet 46 of the housing 28 and the carrier body 24 is allowed to cool. Once the operating temperature of the processed carrier body 24 has cooled, the processed carrier body 24 can be removed from the chamber 30. The processed carrier body 24 is then removed and a new carrier body 24 is placed in the manufacturing apparatus 20.

### Examples

Various examples were prepared to illustrate corrosion resistance of sample coupons that are formed from nickel, with various coatings disposed thereon as described in Table 1 below. While various coupons were prepared with materials that are suitable for the exterior coating 98 only, such coupons are not comparative examples but rather illustrate suitable materials for the exterior coating 98 as opposed to the contact region coating 96.

TABLE 1

| | Coupon Material | Coating |
|---|---|---|
| Example 1 | Nickel | PVD Diamond-like carbon, 2.5 μm |
| Example 2 | Nickel | PVD Diamond-like carbon, 5.5 μm |
| Example 3 | Nickel | DCD Diamond-like carbon, 1.5 μm |
| Example 4 | Nickel | TiN/TiOx, 7.0 μm |
| Example 5 | Nickel | TiN, 6.0 μm |
| Example 6 | Nickel | Rhodium |
| Example 7 | Nickel | Platinum |
| Example 8 | Nickel | TiN |

The coupons for Examples 1-5 were placed in an environment of hydrogen at 350° C. and left for 5 hours. The weights of the coupons were recorded before and after each run. The initial and final physical condition of the coupons (e.g., surface bubbling and degradation) was also observed. The results of the testing are provided in Table 2 below.

TABLE 2

| | | | | | % | |
|---|---|---|---|---|---|---|
| | | Approx. | | | Change | |
| | | Initial | | | of | Surface |
| | Initial | Coating | Final | Differ- | Coating | Bubbling/ |
| | Wt., g | Mass, g | Wt., g | ence, g | Weight | Degradation |
| Example 1 | 15.1745 | 0.0190 | 15.1691 | 0.0054 | −29% | Moderate |
| Example 2 | 12.0867 | 0.0410 | 12.0750 | 0.0117 | −28% | Moderate |
| Example 3 | 14.1901 | 0.0110 | 14.1899 | 0.0002 | −2% | None |
| Example 4 | 16.1213 | 0.0890 | 16.1139 | 0.0074 | −8% | Low |
| Example 5 | 16.2107 | 0.0780 | 16.2033 | 0.0074 | −9% | Low |

The coupons for Examples 6 and 7 were placed in an environment of hydrogen and trichlorosilane at 350° C. and left for 5 hours. The weights of the coupons were recorded before and after each run. The initial and final physical condition of the coupons (e.g., surface bubbling and degradation) was also observed. The results of the testing are provided in Table 3 below.

TABLE 3

| | | | | Surface Bubbling/ |
|---|---|---|---|---|
| | Initial Wt., g | Final Wt., g | Difference, g | Degradation |
| Example 6 | 17.4585 | 17.4612 | 0.0027 | None |
| Example 7 | 17.4339 | 17.4478 | 0.0139 | Moderate |

The coupon for Example 8 was placed in an environment of hydrogen and trichlorosilane at 450° C. and left for 5 hours. The weight of the coupon was recorded before and after the run. The initial and final physical condition of the coupon (e.g., surface bubbling and degradation) was also observed. The coupon had an initial weight of 18.0264 g and a final weight of 18.0266 g for a weight difference of 0.0002 g, and exhibited no surface bubbling or degradation.

Obviously, many modifications and variations of the present invention are possible in light of the above teachings, and the invention may be practiced otherwise than as specifically described within the scope of the appended claims. It is to be understood that the appended claims are not limited to express and particular compounds, compositions, or methods described in the detailed description, which may vary between particular embodiments which fall within the scope of the appended claims. With respect to any Markush groups relied upon herein for describing particular features or aspects of various embodiments, it is to be appreciated that different, special, and/or unexpected results may be obtained from each member of the respective Markush group independent from all other Markush members. Each member of a Markush group may be relied upon individually and or in combination and provides adequate support for specific embodiments within the scope of the appended claims.

It is also to be understood that any ranges and subranges relied upon in describing various embodiments of the present invention independently and collectively fall within the scope of the appended claims, and are understood to describe and contemplate all ranges including whole and/or fractional values therein, even if such values are not expressly written herein. One of skill in the art readily recognizes that the enumerated ranges and subranges sufficiently describe and enable various embodiments of the present invention, and such ranges and subranges may be further delineated into relevant halves, thirds, quarters, fifths, and so on. As just one example, a range “of from 0.1 to 0.9” may be further delineated into a lower third, i.e., from 0.1 to 0.3, a middle third, i.e., from 0.4 to 0.6, and an upper third, i.e., from 0.7 to 0.9, which individually and collectively are within the scope of the appended claims, and may be relied upon individually and/or collectively and provide adequate support for specific embodiments within the scope of the appended claims. In addition, with respect to the language which defines or modifies a range, such as “at least,” “greater than,” “less than,” “no more than,” and the like, it is to be understood that such language includes subranges and/or an upper or lower limit. As another example, a range of “at least 10” inherently includes a subrange of from at least 10 to 35, a subrange of from at least 10 to 25, a subrange of from 25 to 35, and so on, and each subrange may be relied upon individually and/or collectively and provides adequate support for specific embodiments within the scope of the appended claims. Finally, an individual number within a disclosed range may be relied upon and provides adequate support for specific embodiments within the scope of the appended claims. For example, a range “of from 1 to 9” includes various individual integers, such as 3, as well as individual numbers including a decimal point (or fraction), such as 4.1, which may be relied upon and provide adequate support for specific embodiments within the scope of the appended claims.

1. A manufacturing apparatus for deposition of a material on a carrier body having a first end and a second end spaced from each other with a socket disposed at each end of the carrier body, said apparatus comprising:
a housing defining a chamber;
an inlet defined through said housing for introducing a gas into the chamber;
an outlet defined through said housing for exhausting the gas from the chamber;
at least one electrode having an exterior surface having a contact region adapted to contact the socket, said electrode disposed through said housing with said electrode at least partially disposed within the chamber for coupling with the socket;
a power supply device coupled to said electrode for providing an electrical current to said electrode; and
a contact region coating disposed on said contact region of said electrode for maintaining electrical conductivity between said electrode and the socket, said contact region coating having an electrical conductivity of at least 7×10⁶ Siemens/meter at room temperature and a greater wear resistance than nickel as measured in mm³/N*m.

2. A manufacturing apparatus as set forth in claim 1 wherein said electrode is formed from a base metal and wherein said contact region coating is disposed directly on said base metal of said electrode.

3. A manufacturing apparatus as set forth in claim 2 wherein said base metal is selected from the group of copper, silver, nickel, Inconel®, gold, and combinations thereof.

4. A manufacturing apparatus as set forth in claim 1 wherein said contact region coating is further defined as one of a physical vapor deposition coating or a plasma-assisted chemical vapor deposition coating.

5. A manufacturing apparatus as set forth in claim 1 wherein said contact region coating is further defined as a dynamic compound deposition coating.

6. A manufacturing apparatus as set forth in claim 1 wherein said contact region coating has a wear resistance of at least 6×10⁶ mm³/N*m per ASTM G99-5.

7. A manufacturing apparatus as set forth in claim 1 wherein said contact region coating comprises a titanium-containing compound having an electrical conductivity of at least 7×10⁶ Siemens/meter at room temperature.

8. A manufacturing apparatus as set forth in claim 1 wherein said electrode further comprises an exterior coating disposed on said electrode outside of said contact region.

9. A manufacturing apparatus as set forth in claim 8 wherein said exterior coating is different than said contact region coating.

10. A manufacturing apparatus as set forth in claim 9 wherein said exterior coating has an electrical conductivity of less than 7×10⁶ Siemens/meter at room temperature.

11. A manufacturing apparatus as set forth in claim 10 wherein said exterior coating comprises a diamond-like carbon compound.

12. A manufacturing apparatus as set forth in claim 1 wherein said electrode further includes:
a shaft having a first end and a second end; and
a head disposed on one of said ends of said shaft wherein said head of said electrode defines said exterior surface having said contact region.

13. A manufacturing apparatus as set forth in claim 12 wherein at least one of said head and said shaft is free from a coating disposed on said exterior surface thereof outside of said contact region.

14. A manufacturing apparatus as set forth in claim 1 wherein said at least one electrode includes a first electrode for receiving the socket at the first end of the carrier body and a second electrode for receiving the socket at the second end of the carrier body.

15. An electrode for use with a manufacturing apparatus to deposit a material onto a carrier body having a first end and a second end spaced from each other with a socket disposed at each end of the carrier body, said electrode comprising:
a shaft having a first end and a second end;
a head disposed on one of said ends of said shaft for coupling with the socket;
wherein said head has an exterior surface having a contact region adapted to contact the socket; and
a contact region coating disposed on said contact region of said electrode for maintaining electrical conductivity between said electrode and the socket, said contact region coating having an electrical conductivity of at least 7×10⁶ Siemens/meter at room temperature and a greater wear resistance than nickel as measured in mm³/N*m.

16. An electrode as set forth in claim 15 wherein said electrode is formed from a base metal and wherein said contact region coating is disposed directly on said base metal of said electrode.

17. An electrode as set forth in claim 16 wherein said base metal is selected from the group of copper, silver, nickel, Inconel®, gold, and alloys thereof.

18. An electrode as set forth in claim 1 wherein said contact region coating is further defined as one of a physical vapor deposition coating or a plasma-assisted chemical vapor deposition coating.

19. An electrode as set forth in claim 15 wherein said contact region coating is further defined as a dynamic compound deposition coating.

20. An electrode as set forth in claim 15 wherein said electrode defines a cup with said contact region located within a portion of the cup.

21. An electrode as set forth in claim 20 wherein said contact region is only located on side walls of the cup.

22. An electrode as set forth in claim 15 wherein said contact region coating comprises a titanium-containing compound having an electrical conductivity of at least 7×10⁶ Siemens/meter at room temperature.

23. An electrode as set forth in claim 21 wherein an exterior coating is disposed on said bottom of the cup.

24. An electrode as set forth in claim 15 wherein an exterior coating is disposed on said electrode outside of said contact region.

25. An electrode as set forth in claim 23 wherein said exterior coating is different than said contact region coating.

26. An electrode as set forth in claim 25 wherein said exterior coating has an electrical conductivity of less than 7×10⁶ Siemens/meter at room temperature.

27. An electrode as set forth in claim 26 wherein said exterior coating comprises a diamond-like carbon compound.

28. An electrode as set forth in claim 15 wherein at least one of said head and said shaft is free from a coating disposed on said exterior surface thereof outside of said contact region.

29-33. (canceled)
